(19) United States
(12) Patent Application Publication
(10) Pub. No.: US 2008/0035052 A1
(43) Pub. Date: Feb. 14, 2008

(54) METHOD FOR MANUFACTURING A SEMICONDUCTOR SUBSTRATE

(75) Inventor: Cheng-Chuan CHEN, Tainan Hsien (TW)

Correspondence Address: FOLEY AND LARDNER LLP;SUITE 500, 3000 K STREET NW, WASHINGTON, DC, 20007, US

(73) Assignee: GENESIS PHOTONICS INC.

(21) Appl. No.: 11/874,358

(22) Filed: Oct. 18, 2007

Related U.S. Application Data
(63) Continuation-in-part of application No. 11/585,175, filed on Oct. 24, 2006.
Application No. 11/585,175 is a continuation-in-part of application No. 11/062,490, filed on Feb. 23, 2005, now Pat. No. 7,157,293.
Application No. 11/585,175 is a continuation-in-part of application No. 11/417,008, filed on May 2, 2006.

(51) Int. Cl. H01L 21/02; C30B 23/00

(52) U.S. Cl. 117/95; 117/105; 117/950; 117/951

(57) ABSTRACT

A method for manufacturing a semiconductor substrate includes: (a) forming a protrusion-patterned layer on an epitaxial substrate, the protrusion-patterned layer including a plurality of separated protrusions, each of which includes a top end portion distal from the epitaxial substrate; (b) laterally growing a base layer on the top end portions of the protrusions of the protrusion-patterned layer to a predetermined layer thickness under an epitaxial temperature higher than room temperature in such a manner that each of the top end portions is covered by the base layer and that the base layer cooperates with the protrusions to define a plurality of cavities thereamong; and (c) separating the base layer from the epitaxial substrate by destroying the protrusions of the protrusion-patterned layer.

### CROSS-REFERENCE TO RELATED APPLICATIONS

This application is a continuation-in-part of U.S. patent application Ser. No. 11/585,175 (hereinafter referred to as the '175 application). The '175 application, entitled “Method for Manufacturing a Semiconductor Device,” was filed on Oct. 24, 2006 and claims priority of Taiwanese application no. 095115898. The '175 application is a continuation-in-part of U.S. patent application Ser. Nos. 11/062,490 (hereinafter referred to as the '490 application) and 11/417,008 (hereinafter referred to as the '008 application). The '490 application, entitled “Method for Making a Semiconductor Light Emitting Device,” was filed on Feb. 23, 2005 and claims priority of Taiwanese application no. 093131968, filed on Oct. 21, 2004. The '008 application, entitled “Method for Manufacturing a Semiconductor Device,” was filed on and May 2, 2006 and claims priority of Taiwanese application no. 094114375, filed on May 4, 2005.

### BACKGROUND OF THE INVENTION

1. Field of the Invention

This invention relates to a method for manufacturing a semiconductor substrate, more particularly to a method for manufacturing a semiconductor substrate involving forming a protrusion-patterned layer on an epitaxial substrate, laterally growing a base layer on the protrusion-patterned layer, and separating the base layer from the epitaxial substrate by destroying the protrusion-patterned layer.

2. Description of the Related Art

Referring to FIG. 1, a semiconductor substrate 13 for epitaxial growth of a gallium nitride-based light emitting diode is conventionally formed by epitaxial growth and laser-assisted lift-off techniques. In detail, the semiconductor substrate 13 is manufactured by preparing an epitaxial substrate 11 made of sapphire (α-Al₂O₃), forming a gallium nitride film 12 having a thickness of 2 μm to 10 μm on the epitaxial substrate 11 through metal organic chemical vapor deposition (MOCVD) techniques, and thickening the gallium nitride film 12 to a predetermined thickness, generally ranging from 300 μm to 500 μm, through hydride vapor phase epitaxy (HVPE) techniques. Finally, a laser is applied to a boundary between the epitaxial substrate 11 and the gallium nitride film 12 so as to break bonding therebetween and so as to separate the epitaxial substrate 11 from the gallium nitride film 12.

Advantageously, the expensive epitaxial substrate 11 of sapphire (α-Al₂O₃) used in the above method can be reused, after being subjected to a suitable surface treatment. However, in the above method, numerous dislocations resulting from the epitaxial substrate 11 will extend into the semiconductor substrate 13 and can cause the semiconductor substrate 13 to have a defect density ranging from 10⁹ to 10¹⁰ cm⁻². In addition, the bonding strength of the boundary between the epitaxial substrate 11 and the gallium nitride film 12 is not even, and bond-breaking operation of the boundary can result in surface damage to the semiconductor substrate 13. Hence, production yield of the semiconductor substrate 13 and quality of the light emitting device utilizing such semiconductor substrate 13 are unsatisfactory.

In addition, it is known in the art that the defect density of the semiconductor substrate 13 will decrease with an increase in the thickness thereof. Particularly, when the semiconductor substrate 13 has a thickness as much as 5 mm or more, the defect density can be reduced to less than 10⁶ cm⁻². Hence, in order to manufacture the semiconductor substrate 13 with a relatively low defect density, the skilled artisan tends to form a relatively thick layer on the epitaxial substrate 11. The thick layer is then cut into the required thickness after being separated from the epitaxial substrate 11 so as to form the semiconductor substrate 13.

However, with an increase in thickness required by the semiconductor substrate 13, e.g., when the gallium nitride film 12 grows on the epitaxial substrate 11 to a thickness larger than 500 μm, even up to 10 mm, the gallium nitride film 12 will crack due to difference in releasing of heat stress between the gallium nitride film 12 and the epitaxial substrate 11 during cooling of the epitaxial substrate 11 and the gallium nitride film 12 from an epitaxial temperature of about 950° C. to room temperature (25° C.). Hence, the semiconductor substrate 13 having a thickness larger than 500 μm is relatively difficult to prepare.

### SUMMARY OF THE INVENTION

Therefore, the object of the present invention is to provide an economical method for manufacturing a semiconductor substrate of gallium nitride with improved quality.

According to the present invention, a method for manufacturing a semiconductor substrate includes the steps of: (a) forming a protrusion-patterned layer on an epitaxial substrate, the protrusion-patterned layer including a plurality of separated protrusions, each of which includes a top end portion distal from the epitaxial substrate; (b) laterally growing a base layer on the top end portions of the protrusions of the protrusion-patterned layer to a predetermined layer thickness under an epitaxial temperature higher than room temperature in such a manner that each of the top end portions is covered by the base layer and that the base layer cooperates with the protrusions to define a plurality of cavities thereamong; and (c) separating the base layer from the epitaxial substrate by destroying the protrusions of the protrusion-patterned layer.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a schematic flow diagram to illustrate a conventional method for forming a semiconductor substrate involving laser-assisted lift-off techniques;

FIG. 2 is a fragmentary schematic view to illustrate the step of forming a seed layer on an epitaxial substrate in the first preferred embodiment of a method for manufacturing a semiconductor substrate according to this invention;

FIG. 3 is a fragmentary schematic view to illustrate the step of forming a protrusion-patterned layer on the seed layer in the first preferred embodiment of the method of this invention;

FIG. 4 is a fragmentary schematic view to illustrate the step of forming a barrier layer on the protrusion-patterned layer in the first preferred embodiment of the method of this invention;

FIG. 5 is a fragmentary schematic view to illustrate a first stage of a two-stage process for laterally growing a base layer on the barrier layer in the first preferred embodiment of the method of this invention;

FIG. 6 is a fragmentary schematic view to illustrate a second stage of the two-stage process for laterally growing the base layer in the first preferred embodiment of the method of this invention;

FIG. 7 is a fragmentary schematic view to illustrate the step of separating the base layer from the epitaxial substrate in the first preferred embodiment of the method of this invention;

FIG. 8 is a fragmentary schematic view to illustrate the step of forming a protrusion-patterned layer on an epitaxial substrate in the second preferred embodiment of the method of this invention;

FIG. 9 is a fragmentary schematic view to illustrate the step of forming a barrier layer on the protrusion-patterned layer in the second preferred embodiment of the method of this invention;

FIG. 10 is a fragmentary schematic view to illustrate a first stage of a two-stage process for laterally growing a base layer on the barrier layer in the second preferred embodiment of the method of this invention;

FIG. 11 is a fragmentary schematic view to illustrate a second stage of the two-stage process for laterally growing the base layer in the second preferred embodiment of the method of this invention; and

FIG. 12 is a fragmentary schematic view to illustrate the step of separating the base layer from the epitaxial substrate in the second preferred embodiment of the method of this invention.

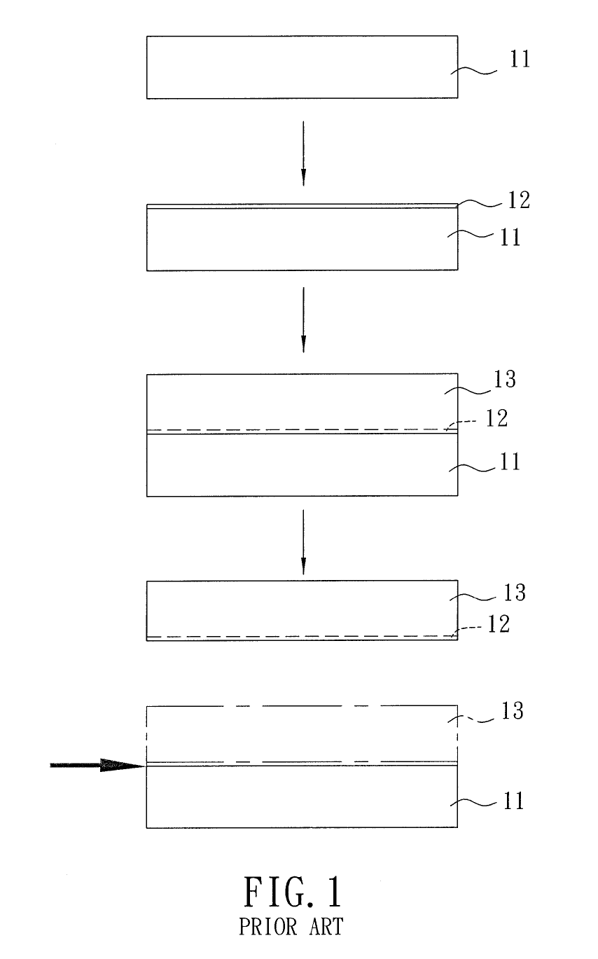

### DETAILED DESCRIPTION OF THE PREFERRED EMBODIMENTS

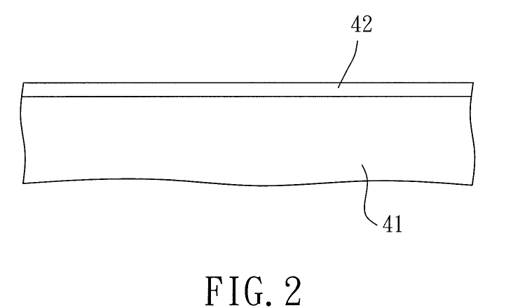

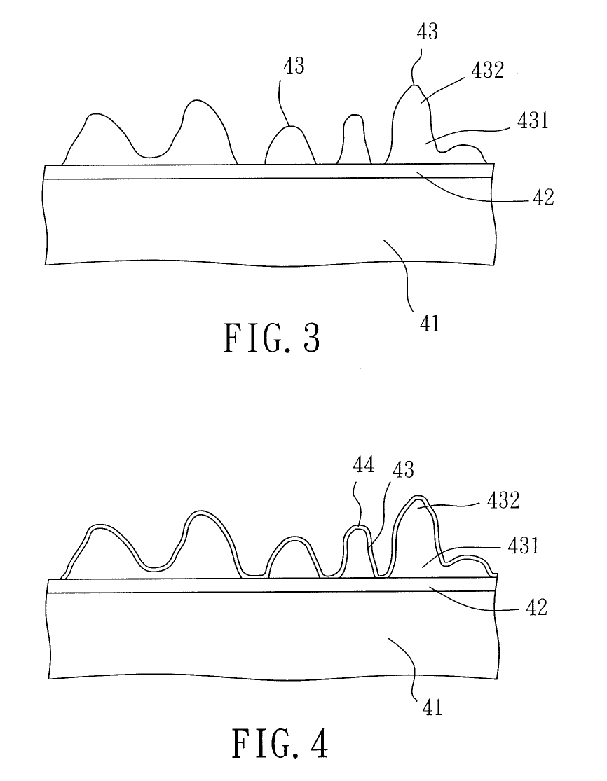

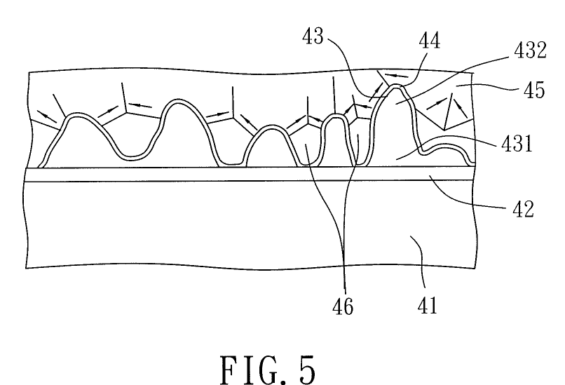

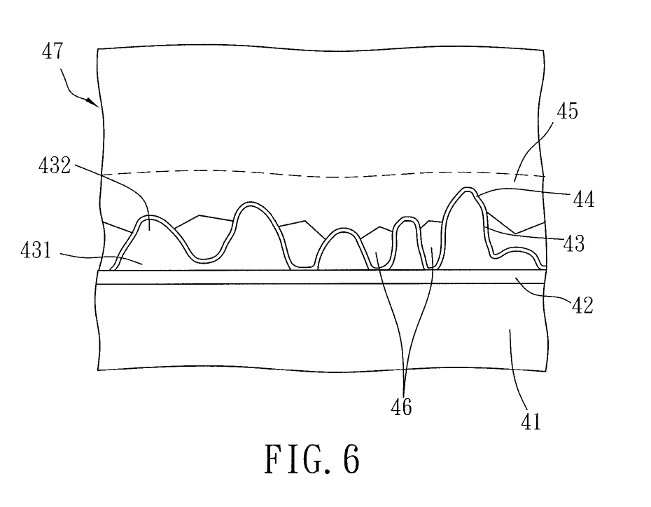

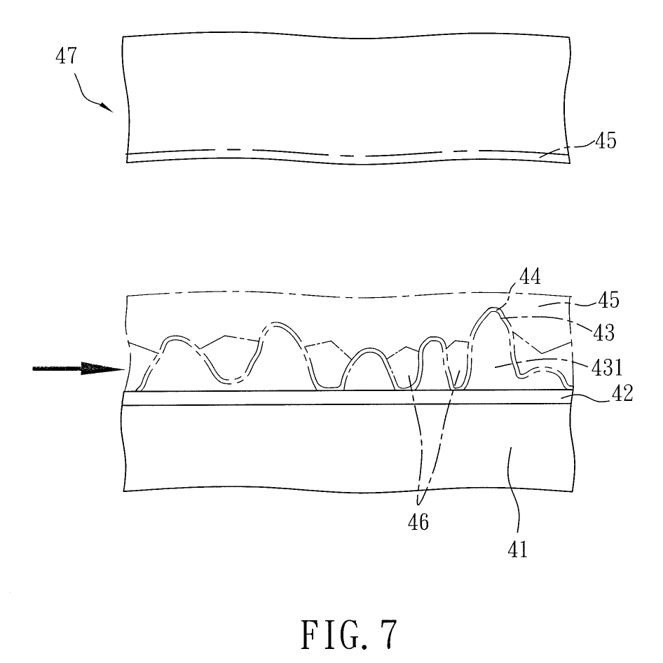

FIGS. 2 to 7 illustrate consecutive steps of a method of the first preferred embodiment according to this invention for manufacturing a semiconductor substrate 47. The method of the first preferred embodiment includes the steps of: forming a protrusion-patterned layer on an epitaxial substrate 41 (FIG. 3), the protrusion-patterned layer including a plurality of separated protrusions 43, each of which includes a base portion 431 formed on the epitaxial substrate 41 and a top end portion 432 opposite to the base portion 431 and distal from the epitaxial substrate 41; laterally growing a base layer 45 on the top end portions 432 of the protrusions 43 of the protrusion-patterned layer to a predetermined layer thickness under an epitaxial temperature higher than room temperature in such a manner that each of the top end portions 432 is covered by the base layer 45 and that the base layer 45 cooperates with the protrusions 43 to define a plurality of cavities 46 thereamong (FIGS. 5 and 6); and separating the base layer 45 from the epitaxial substrate 41 by destroying the protrusions 43 of the protrusion-patterned layer (FIG. 7).

In one preferred embodiment, the lateral growth of the base layer 45 to the predetermined layer thickness is conducted through a two-stage process involving two kinds of deposition techniques. In the first stage, the base layer 45 is laterally grown on the top end portions 432 of the protrusions 43 of the protrusion-patterned layer (FIG. 5) through metal organic chemical vapor deposition (MOCVD) techniques, while in the second stage, the base layer 45 is thickened to the predetermined layer thickness (FIG. 6) through hydride vapor phase epitaxy (HVPE) techniques.

In another preferred embodiment, the lateral growth of the base layer 45 to the predetermined layer thickness is conducted through a one-stage process involving only one deposition technique, such as hydride vapor phase epitaxy (HVPE) techniques.

Non-limiting examples of the material used for manufacture of the epitaxial substrate 41 include sapphire (α-Al₂O₃), silicon carbide (SiC), zinc oxide (ZnO), aluminum nitride (AlN), and silicon (Si).

Preferably, referring to FIG. 2, prior to formation of the protrusion-patterned layer on the epitaxial substrate 41, a seed layer 42 is formed on the epitaxial substrate 41. The seed layer 42 has a lattice constant mismatched with those of the epitaxial substrate 41 and the protrusion-patterned layer.

More preferably, the seed layer 42 is made from a silicon nitride (Si₃N₄)-based compound. Most preferably, the seed layer 42 is made from silicon nitride (Si₃N₄).

As an example, the formation of the protrusion-patterned layer and the seed layer 42 on the epitaxial substrate 41 may be conducted by placing the epitaxial substrate 41 of sapphire on a susceptor in a reactor (not shown), subsequently heating the susceptor to a temperature of 600° C., followed by introducing a mixed flow of about 40 standard cubic centimeter per minute (sccm) of silane (SiH_{4(g)}) and about 40 standard liter per minute (slm) of ammonia (NH_{3(g)}) into the reactor. Consequently, the seed layer 42 of silicon nitride having a thickness larger than 1 Å is formed on the sapphire substrate 41 through reaction of silane with ammonia. Next, a hydrogen gas is introduced into the reactor, and the temperature of the susceptor is raised to 1100° C. for annealing the sapphire substrate 41 and the seed layer 42 formed thereon.

After formation of the seed layer 42 on the sapphire substrate 41, referring to FIG. 3, the protrusion-patterned layer may be formed on the seed layer 42 through metal organic chemical vapor deposition (MOCVD) techniques at a reaction temperature ranging from 500° C. to 1000° C. As an example, the formation of the protrusion-patterned layer may be conducted by lowering the temperature of the susceptor to 800° C., and a mixed flow of 50 sccm of trimethylgallium (TMGa_{(g)}), 20 slm of NH_{3(g)}, and 0.5 sccm of SiH_{4(g)}, is introduced into the reactor, thereby forming the protrusion-patterned layer of GaN that includes a plurality of separated protrusions 43 on the seed layer 42. The base portion 431 of each protrusion 43 is epitaxially formed on the seed layer 42, and the top end portion 432 of each protrusion 43 extends from the base portion 431 in a substantially normal direction relative to the sapphire substrate 41 away from the seed layer 42. It is noted that if SiH_{4(g)} is not introduced into the reactor during formation of the protrusion-patterned layer, the height-to-width ratio of each of the separated protrusions 43 will be reduced. Preferably, each of the protrusions 43 of the protrusion-patterned layer has an island shape.

Preferably, each of the protrusion-patterned layer and the base layer 45 is independently made from a gallium nitride-based compound. More preferably, the gallium nitride-based compound has a formula of AlₓIn_{y}Ga_{1-x-y}N, in which x≧0, y≧0, and 1−x−y>0.

Preferably, referring to FIG. 4, prior to formation of the base layer 45 on the protrusion-patterned layer, a barrier layer 44 is formed on the protrusion-patterned layer. More preferably, the barrier layer 44 has a lattice constant mismatched with that of the protrusion-patterned layer.

Preferably, the barrier layer 44 is made from a silicon nitride (Si₃N₄)-based compound. More preferably, the barrier layer 44 is made from silicon nitride (Si₃N₄). As an example, the formation of the barrier layer 44 may be conducted by maintaining supply of NH_{3(g)} and subsequently increasing supply of SiH_{4(g)} to a flow rate of about 40 sccm. The barrier layer (Si₃N₄) 44 is formed on both the protrusion-patterned layer and a portion of the seed layer 42 that is not covered by the protrusion-patterned layer, as shown in FIG. 4. The barrier layer 44 thus formed has a thickness larger than 1 Å.

After formation of the barrier layer 44 on the protrusion-patterned layer, referring to FIG. 5, the base layer 45 may be laterally grown on the top end portions 432 of the protrusions 43 of the protrusion-patterned layer. Preferably, the formation of the base layer 45 on the top end portions 432 of the protrusions 43 of the protrusion-patterned layer is conducted by reacting a gallium source gas with an ammonia gas at an epitaxial temperature ranging from 900° C. to 1500° C.

As an example, the formation of the base layer 45 may be conducted by raising the temperature of the susceptor to about 1000° C., followed by introducing 120 sccm of TMGa_{(g)} and 20 slm of NH_{3(g)} into the reactor. The base layer 45 of GaN is lateral-epitaxially grown on portions of the barrier layer 44 formed on the top end portions 432 of the protrusions 43 of the protrusion-patterned layer in directions shown by the arrows (see FIG. 5), and has a thickness larger than 1 μm. The base layer 45 cooperates with the protrusions 43 covered with the barrier layer 44 to define a plurality of cavities 46 thereamong.

After the formation of the base layer 45, referring to FIG. 6, the base layer 45 is thickened to a predetermined thickness so as to form the semiconductor substrate 47. Preferably, the thickening operation of the base layer 45 is conducted through hydride vapor phase epitaxy (HVPE) techniques, and the thickened base layer 45 has a thickness ranging from 400 μm to 600 μm.

Alternatively, the lateral growth of the base layer 45 using TMGa_{(g)} and NH_{3(g)} at a temperature higher than 900° C. can be performed using HVPE techniques so as to achieve the desired thickness of the base layer 45, e.g., 400 μm to 600 μm.

After thickening the base layer 45, referring to FIG. 7, the base layer 45 is separated from the epitaxial substrate 41 by destroying the protrusions 43 of the protrusion-patterned layer, thereby separating the semiconductor substrate 47 from the epitaxial substrate 41.

The destruction of the protrusions 43 of the protrusion-patterned layer may be conducted using wet-etching techniques. The cavities 46 among the protrusions 43 permit an etching solution, such as solutions of potassium hydroxide (KOH), hydrochloric acid (HCl), phosphoric acid (H₃PO₄), and nitro-hydrochloric acid (aqua regia), to penetrate therethrough, thereby facilitating wet etching of the protrusions 43.

In another preferred embodiment, the destruction of the protrusions 43 of the protrusion-patterned layer may be conducted through laser-assisted lift-off techniques.

In yet another preferred embodiment, the destruction of the protrusions 43 of the protrusion-patterned layer may be conducted by cooling an assembly of the base layer 45, the barrier layer 44, the protrusion-patterned layer, and the epitaxial substrate 41 from the epitaxial temperature to the room temperature. Since releasing of heat stress for the epitaxial substrate 41 during cooling are different from that of the base layer 45, the base portions 431 of the protrusions 43 crack during cooling so as to simply separate the semiconductor substrate 47 from the epitaxial substrate 41.

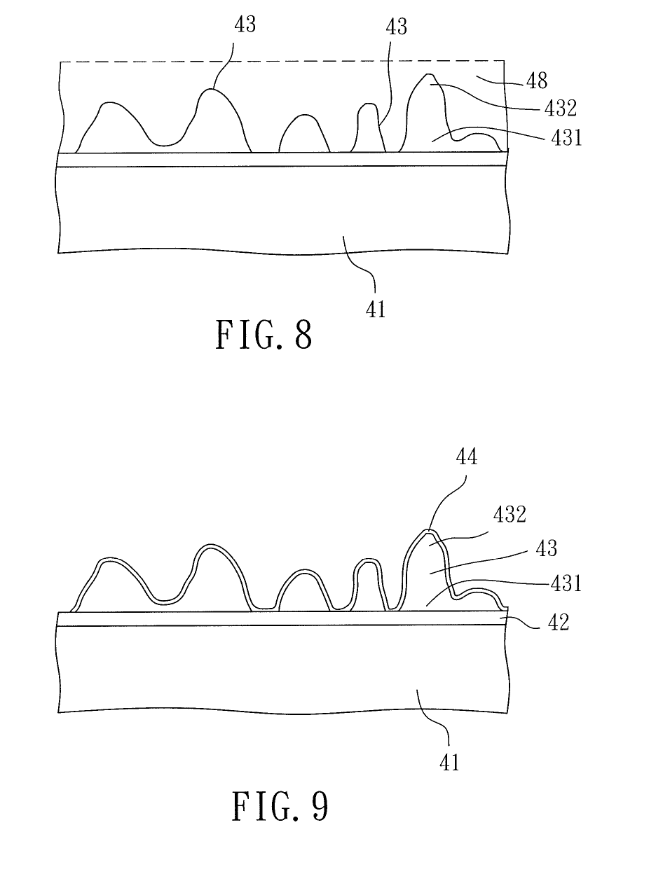

FIGS. 8 to 12 illustrate consecutive steps of a method of the second preferred embodiment according to this invention for manufacturing a semiconductor substrate 47. The second preferred embodiment differs from the first preferred embodiment in the step of forming the protrusion-patterned layer on the epitaxial substrate 41. In this embodiment, the formation of the protrusion-patterned layer on the epitaxial substrate 41 includes the steps of: forming a lower temperature-formed continuous layer 48 of a gallium nitride-based compound on the epitaxial substrate 41 by reacting gallium source gas with ammonia gas at a reaction temperature ranging from 450° C. to 750° C.; and subsequently raising the reaction temperature to 900° C. to 1100° C. and lowering the partial pressure of the ammonia gas so as to convert structurally the lower temperature-formed continuous layer 48 of the gallium nitride-based compound into the protrusion-patterned layer (see FIG. 8).

As an example, a mixed flow of 15 sccm of TMGa_{(g)} and 20 slm of NH_{3(g)} is introduced into a reactor at a temperature of 600° C. so as to form the lower temperature-formed continuous layer 48 of GaN covering the sapphire substrate 41. Next, the temperature is raised to 950° C., and the partial pressure of NH_{3(g)} is lowered through reduction of the flow rate of NH_{3(g)} to 6 slm, thereby converting structurally the lower temperature-formed continuous layer 48 into the protrusion-patterned layer including a plurality of separated protrusions 43. Each protrusion 43 includes the base portion 431 formed on the epitaxial substrate 41 and the top end portion 432 (See FIG. 8).

After forming the protrusion-patterned layer, supply of NH_{3(g)} is maintained, and supply of SiH_{4(g)} is subsequently increased to a flow rate of about 40 sccm. The barrier layer (Si₃N₄) 44 is formed on both the protrusion-patterned layer and a portion of the seed layer 42 on the sapphire substrate 41 that is not covered by the protrusion-patterned layer. The barrier layer 44 has a thickness larger than 1 Å (see FIG. 9).

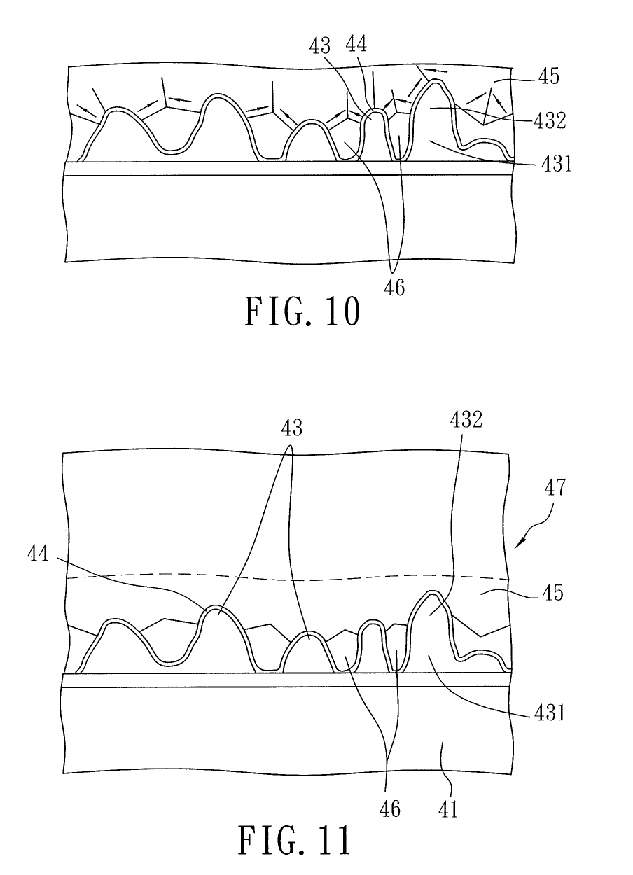

The temperature is subsequently raised to about 1000° C., and 120 sccm of TMGa_{(g)} and 20 slm of NH_{3(g)} are introduced into the reactor so as to conduct formation of the base layer 45 of GaN which is lateral-epitaxially grown on the portions of the barrier layer 44 formed on the top end portions 432 of the protrusions 43 of the protrusion-patterned layer in directions shown by the arrows (see FIG. 10), and which has a thickness larger than 1 μm. The base layer 45 cooperates with the protrusions 43 covered with the barrier layer 44 to define a plurality of cavities 46 thereamong (See FIG. 10).

After the formation of the base layer 45, referring to FIG. 11, the base layer 45 is thickened to a predetermined thickness so as to form the semiconductor substrate 47. Preferably, the thickening operation of the base layer 45 is conducted through hydride vapor phase epitaxy (HVPE) techniques, and the thickened base layer 45 has a thickness ranging from 3 mm to 5 mm.

Similar to the first preferred embodiment, the lateral growth of the base layer 45 using TMGa_{(g)} and NH_{3(g)} at a temperature higher than 900° C. can be performed using HVPE techniques so as to achieve the desired thickness of the base layer 45, e.g., 3 mm to 5 mm.

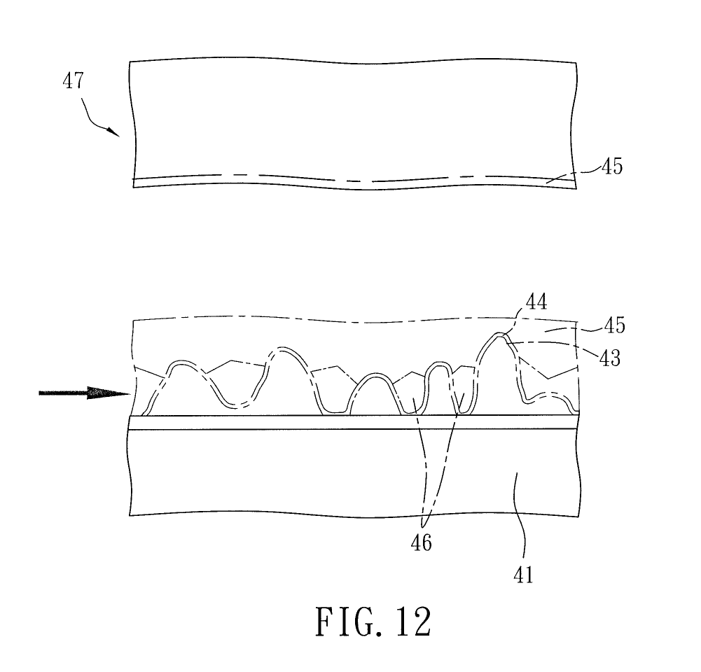

After thickening the base layer 45, referring to FIG. 12, the base layer 45 is separated from the epitaxial substrate 41 by destroying the protrusions 43 of the protrusion-patterned layer, thereby separating the semiconductor substrate 47 from the epitaxial substrate 41.

In addition, similar to the first preferred embodiment, the destruction of the protrusions 43 of the protrusion-patterned layer may be conducted by cooling an assembly of the base layer 45, the barrier layer 44, the protrusion-patterned layer, and the epitaxial substrate 41 from the epitaxial temperature to the room temperature. In particular, the difference in releasing of heat stress between the base layer 45 and the epitaxial substrate 41 can result in destruction of the protrusions 43 of the protrusion-patterned layer without causing damage to the semiconductor substrate 47.

It should be noted that, in the first and second preferred embodiments of this invention, the formation of the seed layer 42 and the barrier layer 44 can be omitted without adversely affecting the quality of the semiconductor substrate 47.

In addition, by virtue of the lateral growth of the base layer 45 on the top end portions 432 of the protrusions 43 and the formation of the cavities 46, dislocations are prevented from extending from the epitaxial substrate 41 upward into the base layer 45 through the seed layer 42 (if present). Particularly, in the first and second preferred embodiments of this invention, the defect density of the base layer 45 and the semiconductor substrate 47 formed of the thickened base layer 45 can be reduced to 10⁵ to 10⁶ cm⁻². Therefore, the quality of the light emitting diode made from the semiconductor substrate 47 can be greatly enhanced.

Particularly, the lateral growth of the base layer 45 to the predetermined thickness can be performed using only one deposition technique, i.e., HVPE. Hence, the process for manufacturing the semiconductor substrate 47 can be simplified.

In particular, the cooling of the base layer 45 in the method can be utilized as a means to destroy the protrusions 43 of the protrusion-patterned layer. In the current relevant art, the difference in releasing of heat stress between the gallium nitride layer 12 and the epitaxial substrate 11 can cause cracking of the semiconductor substrate 13. On the contrary, in the invention, the difference in releasing of heat stress between the base layer 45 and the epitaxial substrate 41 can result in destruction of the protrusions 43 of the protrusion-patterned layer without causing damage to the semiconductor substrate 47.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for manufacturing a semiconductor substrate, comprising:
(a) forming a protrusion-patterned layer on an epitaxial substrate, the protrusion-patterned layer including a plurality of separated protrusions, each of which includes a top end portion distal from the epitaxial substrate;
(b) laterally growing a base layer on the top end portions of the protrusions of the protrusion-patterned layer to a predetermined layer thickness under an epitaxial temperature higher than room temperature in such a manner that each of the top end portions is covered by the base layer and that the base layer cooperates with the protrusions to define a plurality of cavities thereamong; and
(c) separating the base layer from the epitaxial substrate by destroying the protrusions of the protrusion-patterned layer.

2. The method of claim 1, wherein destruction of the protrusions of the protrusion-patterned layer is conducted by cooling an assembly of the base layer, the protrusion-patterned layer and the epitaxial substrate from the epitaxial temperature to the room temperature.

3. The method of claim 1, wherein lateral growth of the base layer is conducted through HVPE techniques.

4. The method of claim 3, wherein destruction of the protrusions of the protrusion-patterned layer is conducted through wet-etching techniques.

5. The method of claim 3, wherein destruction of the protrusions of the protrusion-patterned layer is conducted through laser-assisted lift-off techniques.

6. The method of claim 3, wherein destruction of the protrusions of the protrusion-patterned layer is conducted by cooling an assembly of the base layer, the protrusion-patterned layer and the epitaxial substrate from the epitaxial temperature to the room temperature.

7. The method of claim 1, further comprising forming a barrier layer on the protrusion-patterned layer prior to laterally growing the base layer on the top end portions of the protrusions of the protrusion-patterned layer, the barrier layer having a lattice constant mismatched with that of the protrusion-patterned layer.

8. The method of claim 7, wherein formation of the protrusion-patterned layer on the epitaxial substrate includes:
forming a continuous layer of a gallium nitride-based compound on the epitaxial substrate by reacting gallium source gas with ammonia gas at a reaction temperature ranging from 450° C. to 750° C.; and
subsequently raising the reaction temperature to 900° C. to 1100° C. and lowering the partial pressure of the ammonia gas so as to form the continuous layer of the gallium nitride-based compound into the protrusion-patterned layer.

9. The method of claim 8, wherein the epitaxial substrate is made from a material selected from the group consisting of sapphire (α-Al₂O₃), silicon carbide (SiC), zinc oxide (ZnO), aluminum nitride (AlN), and silicon (Si).

10. The method of claim 8, wherein the gallium nitride-based compound of the continuous layer has a formula of AlₓIn_{y}Ga_{1-x-y}N, in which x≧0, y≧0, and 1−x−y>0.

11. The method of claim 10, wherein the base layer is made from a gallium nitride-based compound.

12. The method of claim 11, wherein the gallium nitride-based compound of the base layer has a formula of AlₓIn_{y}Ga_{1-x-y}N, in which x≧0, y≧0, and 1−x−y>0.

13. The method of claim 7, wherein the barrier layer is made from a silicon nitride (Si₃N₄)-based compound.

14. The method of claim 7, wherein the barrier layer is made from silicon nitride (Si₃N₄).

15. The method of claim 8, wherein formation of the base layer on the top end portions of the protrusions of the protrusion-patterned layer is conducted by reacting a gallium source gas with an ammonia gas at a reaction temperature ranging from 900° C. to 1500° C.

16. The method of claim 8, wherein lateral growth of the base layer is conducted through hydride vapor phase epitaxy (HVPE) techniques.

17. The method of claim 8, wherein destruction of the protrusions of the protrusion-patterned layer is conducted through wet-etching techniques.

18. The method of claim 8, wherein destruction of the protrusions of the protrusion-patterned layer is conducted through laser-assisted lift-off techniques.

19. The method of claim 8, wherein destruction of the protrusions of the protrusion-patterned layer is conducted by cooling an assembly of the base layer, the barrier layer, the protrusion-patterned layer, and the epitaxial substrate from the epitaxial temperature to the room temperature.
